(19) United States
(12) Patent Application Publication
(10) Pub. No.: US 2005/0288815 A1
(43) Pub. Date: Dec. 29, 2005

(54) Semiconductor device manufacturing information service system and server used in the same

(76) Inventors: Kunihiro Kawahara, Sakata (JP); Kazuya Saito, Yawata (JP)

Correspondence Address: HARNESS, DICKEY & PIERCE, P.L.C., P.O. BOX 828, BLOOMFIELD HILLS, MI, 48303, US

(21) Appl. No.: 11/131,609

(22) Filed: May 18, 2005

(30) Foreign Application Priority Data
Jun. 28, 2004 (JP) 2004-189863

(51) Int. Cl. H01L 21/00; G06F 19/00

(52) U.S. Cl. 700/121; 438/5

(57) ABSTRACT

A semiconductor device manufacturing information service system comprises: step control servers, etc. that collect and store manufacturing data indicating the manufacturing result and/or quality in the manufacturing steps accepted by consignee companies X to Z; a manufacturing information service server, in a manufacturing information service company W, that generates customer company basis manufacturing data used in a customer company A by receiving the manufacturing data from the step control servers and changing the data form using a pre-recorded conversion table; and a production and sales control server, in the customer company A, that receives the customer company basis manufacturing data from the manufacturing information service server and displays or prints such data.

### RELATED APPLICATIONS

This application claims priority to Japanese Patent Application No. 2004-189863 filed Jun. 28, 2004 which is hereby expressly incorporated by reference herein in its entirety.

### BACKGROUND

1. Technical Field

The present invention relates to a semiconductor device manufacturing information service system for providing production control information and quality control information to a customer company when another company that supplies semiconductor devices to the customer company produces semiconductor devices by consigning at least one of the manufacturing steps required in a series of semiconductor device manufacturing process, as well as a manufacturing information service server used in such a system.

2. Related Art

FIG. 13 shows a conventional process for manufacturing a semiconductor device. As shown in FIG. 13, in a step S1 for manufacturing a semiconductor device, a front-end processing step (processing step) including epitaxial growth, channel forming, electrode forming, etc. is performed on a semiconductor wafer. Next, in a step S2, a probe test step for testing, using a probe, whether or not each chip is a conforming article is performed.

After the completion of the probe test step, the semiconductor wafer is cut into chips and a post-processing step including die bonding, wire bonding, sealing, etc. is performed for conforming chips in a step S3. Further, a final test step for finally testing whether or not the assembled semiconductor device is a conforming article is performed in a step S4.

In the semiconductor industry, there are many cases of doing business by establishing a corporate body for each of the above steps. A company that receives an order for a semiconductor device from a customer company such as a set maker, etc. consigns part of the manufacture of a semiconductor device to each company that is in charge of each step, and the consignee companies share the manufacture of a semiconductor device. In addition, there is another case where the company that receives the order for a semiconductor device takes charge of any of the manufacturing steps.

On the other hand, the customer company such as a set maker, etc. requires the provision of production control information and quality control information as a service along with the provision of a product. However, when the companies that are in charge of the above steps differ from one another, the data formats of such companies for providing information also differ, which has been causing a difficulty for the customer company in acquiring information. The “format” mentioned above is the form of documents, such as electronic data, facsimile (FAX), etc., that are used for providing data.

Conventionally, a customer company such as a set maker, etc. has been acquiring production control information and quality control information from each of the companies that are in charge of a front-end processing step, a probe test step, and an assembling step, and converting the data formats that are different from company to company into a uniform format before storing the information. Thus, the customer company, that had to unify various formats, has been increasing the production cost.

As a related technique, a remote maintenance system for industrial devices that enables a quick and assured maintenance of devices regardless of regions even in distant places is disclosed in Japanese Unexamined Patent Publication No. 10-97966 (pages 1 and 3, as well as FIG. 1). In such a system, industrial devices including an exposure device, an assembling device, etc. and a host computer that is connected to the industrial devices via LAN are provided in each production facility that is in charge of a front-end processing step or a post-processing step in the manufacture of a semiconductor device. Further, the host computer that monitors the operating condition of the industrial devices is connected, via the Internet, to a vendor's host computer, which also serves as a host control system. Therefore, the communication of maintenance information is possible between the host computer provided in each production facility and the vendor's host computer. However, in Japanese Unexamined Patent Publication No. 10-97966, neither the provision of production control information and quality control information of a semiconductor device to a customer company nor a solution for the difference in data formats among a plurality of companies is disclosed.

Taking the above problem into consideration, the present invention aims to provide a semiconductor device manufacturing information service system that enables a customer company to easily manage the production control information and/or quality control information in each step when a semiconductor device is produced by consigning at least one of the manufacturing steps required in the manufacture of a semiconductor device to at least one consignee company, as well as a manufacturing information service server that is used in such a system.

### SUMMARY

In order to solve the above problem, a semiconductor device manufacturing information service system, according to the present invention, provides information on the manufacture of a semiconductor device to the first company, which is a customer, when a semiconductor device is produced by consigning, from the second company to at least one third company, at least one of manufacturing steps required in the manufacture of a semiconductor device ordered from the first company to the second company. The system comprises: at least one process control server, which is equipped in the at least one third company, that collects and stores manufacturing data indicating a manufacturing result and/or quality in a manufacturing step accepted by the at least one third company; a manufacturing information service server, which is equipped in the second company, that generates manufacturing data, which is to be used in the first company, on a customer company basis by receiving, via a network, the manufacturing data sent from the at least one process control server and changing the form of the manufacturing data using a pre-recorded conversion table; and a production and sales control server, which is equipped in the first company, that receives, via a network, the manufacturing data on a customer company basis sent from the manufacturing information service server and then displays or prints the data.

Here, it is possible that the at least one third company accepts at least one of semiconductor device manufacturing steps including a processing step, a probe test step, an assembling step, and a final test step.

Further, it is possible that the at least one process control server collects and stores manufacturing data containing data indicating a model name and a lot number of a semiconductor device manufactured in the manufacturing step accepted by the at least one third company; or that the at least one process control server collects and stores manufacturing data containing data indicating the test result of a semiconductor device manufactured in the manufacturing step accepted by at least one third company.

Furthermore, it is possible that the manufacturing information service server converts the data indicating a model name and a lot number of a semiconductor device that are used in the at least one third company into data indicating a model name and a lot number of a semiconductor device that are used in the first company.

A manufacturing information service server, according to the present invention is equipped in the second company for providing information on the manufacture of a semiconductor device to the first company, which is a customer, when a semiconductor device is produced by consigning, from the second company to at least one third company, at least one of manufacturing steps required in the manufacture of a semiconductor device ordered from the first company to the second company. The server comprises: a receiving means for receiving, from the at least one process control server equipped in the at least one third company and via a network, manufacturing data indicating the manufacturing result and/or quality in a manufacturing step accepted by the at least one third company; a recording means for recording a conversion table used for converting a manufacturing data form between the at least one third company and the first company; a data generating means for generating manufacturing data on a customer company basis, which is to be used in the first company, by changing, using the conversion table recorded in the recording means, the form of the manufacturing data received from the at least one process control server; and a sending means for sending, via a network, the manufacturing data on a customer company basis generated by the data generating means to the production and sales control server equipped in the first company.

Here, it is possible that the data generating means converts data indicating a model name and a lot number of a semiconductor device that are used in the at least one third company into data indicating a model name and a lot number of a semiconductor device that are used in the first company.

With the present invention, since the manufacturing information service server generates manufacturing data on a customer company basis by receiving, via a network, manufacturing data sent from the process control server equipped in a consignee company and changing the form of the manufacturing data using a pre-recorded conversion table, the customer company can easily manage the production control information and/or quality control information in each step.

### BRIEF DESCRIPTION OF THE DRAWINGS

FIG. 1 is a drawing showing the configuration of a semiconductor device manufacturing information service system according to an embodiment of the present invention.

FIG. 2 is a block diagram showing the details of a processing step control system shown in FIG. 1.

FIG. 3 is a drawing for describing the format of manufacturing data in a consignee company X.

FIG. 4 is a block diagram showing the details of a probe test step control system shown in FIG. 1.

FIG. 5 is a drawing for describing the format of manufacturing data in a consignee company Y.

FIG. 6 is a block diagram showing the details of an assembling step control system shown in FIG. 1.

FIG. 7 is a drawing for describing the format of manufacturing data in a consignee company Z.

FIG. 8 is a block diagram showing the details of a manufacturing information service system shown in FIG. 1.

FIG. 9 is a drawing for describing the manufacturing data that is recorded in a recording unit of the manufacturing information service system.

FIG. 10 is a drawing for describing a customer company basis model master in the manufacturing information service system.

FIG. 11 is a drawing showing a customer company basis manufacturing data that is generated in a customer company basis manufacturing data generating unit.

FIG. 12 is a block diagram showing the details of a production and sales control system shown in FIG. 1.

FIG. 13 is a drawing showing a conventional semiconductor device manufacturing steps.

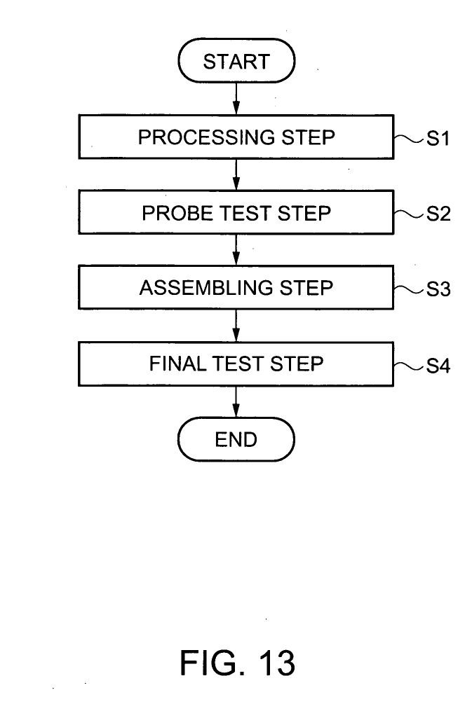

### DETAILED DESCRIPTION

An embodiment of the present invention will now be described in detail with reference to the accompanying drawings. In addition, the descriptions of the same elements are omitted by giving the same reference numerals.

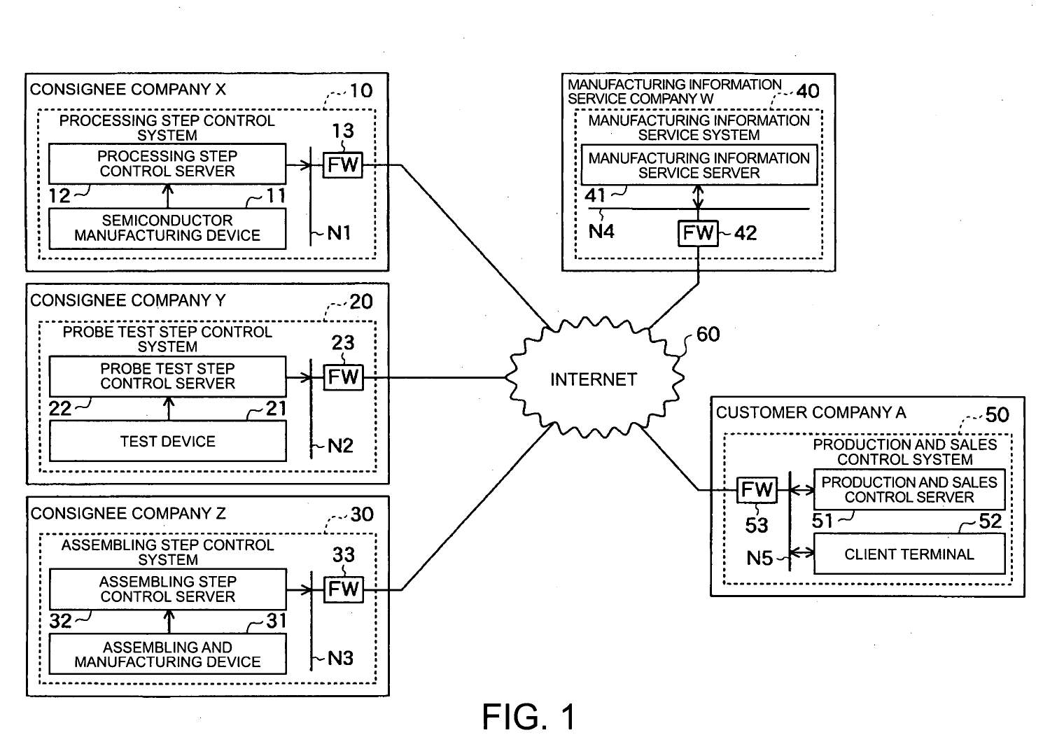

FIG. 1 shows the configuration of a semiconductor device manufacturing information service system according to an embodiment of the present invention. In the semiconductor device manufacturing information service system, for example, a processing step control system 10 of a consignee company X that accepts, from a manufacturing information service company W that is a semiconductor maker, and performs a processing step; a probe test step control system 20 of a consignee company Y that accepts, from the manufacturing information service company W, and performs a probe test step; an assembling step control system 30 of a consignee company Z that accepts, from the manufacturing information service company W, and performs an assembling step and a final test step; a manufacturing information service system 40 of the manufacturing information service company W; and a production and sales control system 50 of a customer company A that orders a semiconductor device to the manufacturing information service company W are connected to one another via an Internet 60.

In the present embodiment, the manufacturing information service system 40 of the manufacturing information service company W converts the model names and lot numbers, etc. used in: the processing step control system 10 of the consignee company X; the probe test step control system 20 of the consignee company Y; and the assembling step control system 30 of the consignee company Z into the model names and lot numbers, etc. used in the production and sales control system 50 of the customer company A. Thus, the lot progress, inventory information, and test result in each step can easily be managed.

The above example describes a shared consignment of the manufacture of a semiconductor device among the three consignee companies X to Z. However, only if there is at least one consignee company, the present invention can be applied. Further, the manufacturing information service company W can also serves as at least one of the consignee companies X to Z. In addition, although there is only the customer company A in FIG. 1, there are generally a plurality of customer companies.

As shown in FIG. 1, the processing step control system 10 comprises a semiconductor manufacturing device 11 used for forming a plurality of chips on each semiconductor wafer in the front-end processing step (processing step), a processing step control server 12 that collects and stores manufacturing data indicating the manufacturing result and/or quality in the processing step, and a firewall (FW) 13 that prevents unauthorized access. Here, the processing step control server 12 is connected to the semiconductor manufacturing device 11, and further to the Internet 60 via a network N1 such as a local area network (LAN), etc. and the FW 13.

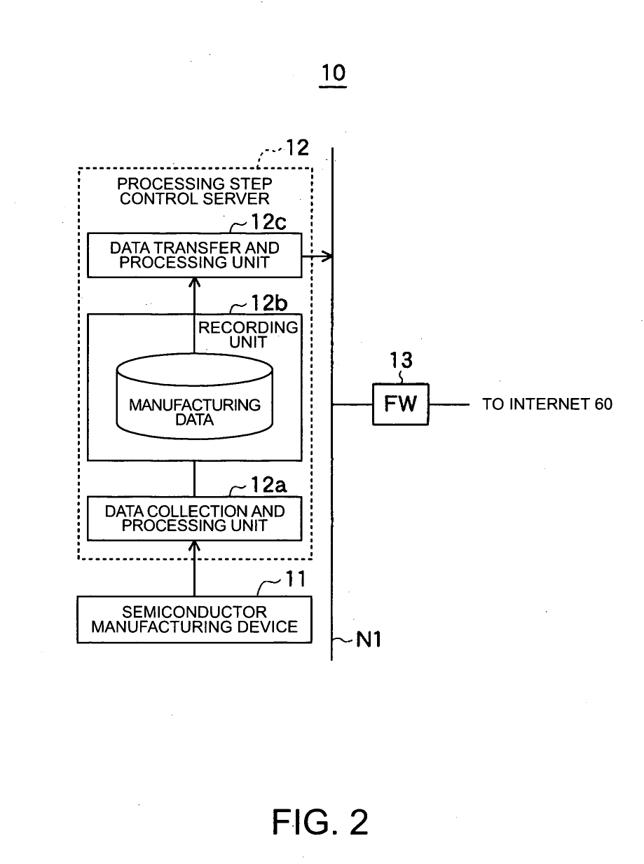

Next, the processing step control system will be described in detail with reference to FIG. 2. In the processing step control system 10, the semiconductor manufacturing device 11 forms a plurality of chips by giving, to each semiconductor wafer, processing steps such as epitaxial growth, channel forming, electrode forming, etc. The semiconductor wafer on which a plurality of chips are formed is shipped to the consignee company Y.

The processing step control server 12 comprises: a data collection and processing unit 12a that collects manufacturing data in the processing step indicating the manufacturing result such as lot progress, inventory information, etc. and/or the quality of the manufactured semiconductor wafer; a recording unit 12b that records the collected manufacturing data; and a data transfer and processing unit 12c that transfers the manufacturing data recorded in the recording unit 12b to the manufacturing information service system 40 (FIG. 1) of the manufacturing information service company W.

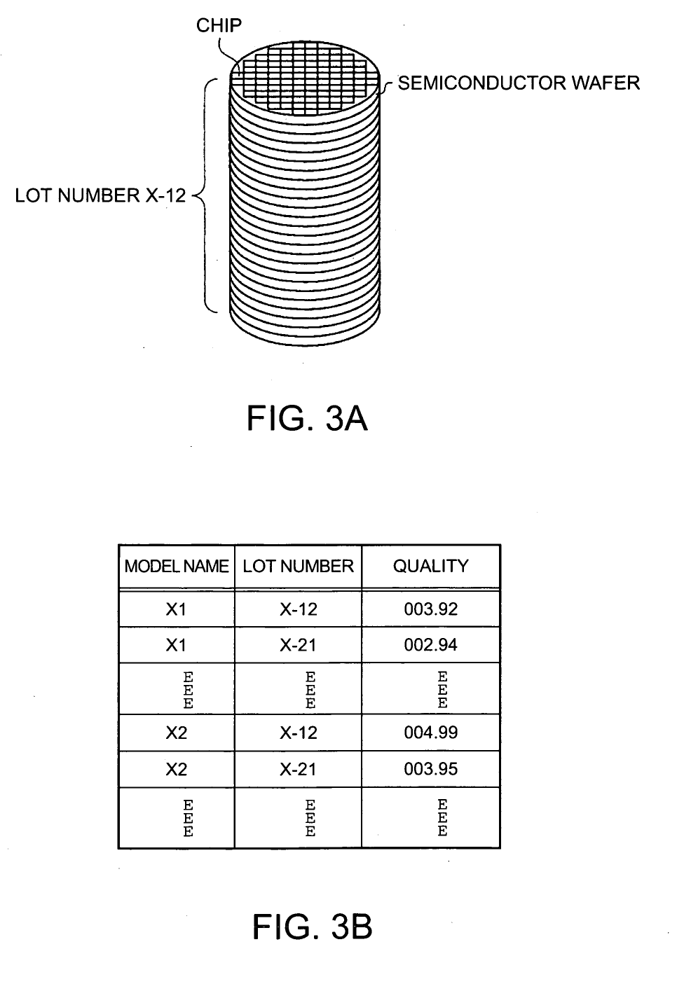

FIG. 3 is a drawing for describing the format of manufacturing data in the consignee company X. As shown in FIG. 3A, the manufacturing data in the consignee company X is expressed in a form in which one lot includes twenty-five semiconductor wafers. Further, as shown in FIG. 3B, the manufacturing data recorded in the recording unit 12b comprises a model name that indicates the type of chips formed on a semiconductor wafer, a lot number that indicates the lot of the semiconductor wafer, and data that indicates the quality of the semiconductor wafer. In addition, the model name, lot number, etc. are expressed in accordance with the form that is used in the consignee company X. In the above example, “X1,” “X2,” etc. are used as the model name and “X-12,” “X-21,” etc. are used as the lot number.

The data transfer and processing unit 12c shown in FIG. 2 reads out the manufacturing data recorded in the recording unit 12b and transfers the read manufacturing data to the manufacturing information service system 40 (FIG. 1) of the manufacturing information service company W via the network N1, the FW 13, and the Internet 60.

Referring to FIG. 1 again, the probe test step control system 20 of the consignee company Y comprises: a test device 21 that tests, using a probe, whether or not each chip formed on a semiconductor wafer is a conforming article; a probe test step control server 22 that collects, from the semiconductor manufacturing device 11, manufacturing data in the probe test step indicating the manufacturing result such as lot progress, inventory information, etc. and/or quality of the manufactured semiconductor wafer including the result of probe test; and an FW 23 that prevents unauthorized access. Here, the probe test step control server 22 is connected to the test device 21, and further to the Internet 60 via a network N2 such as LAN, etc. and the FW 23.

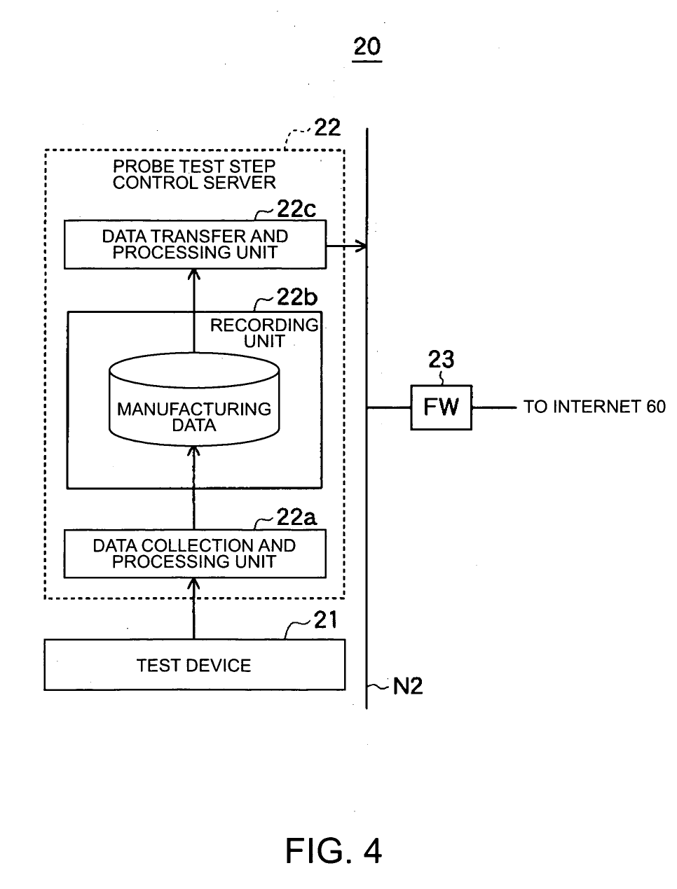

Next, the probe test step control system will be described in detail with reference to FIG. 4. In the probe test step control system 20, the test device 21 checks the electric properties of each chip by applying a specified voltage to each chip formed on a semiconductor wafer that is through with the processing step and measuring the voltage or current, etc. outputted from each chip. With the check performed in the test device 21, whether or not each chip is a conforming article is judged. The semiconductor wafer checked in the test device 21 is shipped to the consignee company Z.

The probe test step control server 22 comprises a data collection and processing unit 22a that collects manufacturing data indicating the test result, etc. in the test device 21, a recording unit 22b that records the collected manufacturing data, and a data transfer and processing unit 22c that transfers the manufacturing data recorded in the recording unit 22b to the manufacturing information service system 40 (FIG. 1) of the manufacturing information service company W.

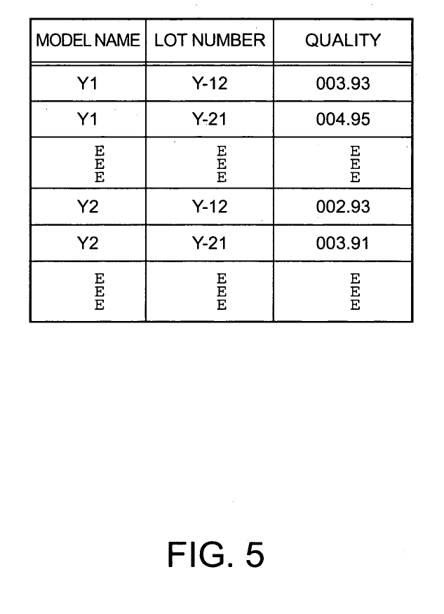

The data collection and processing unit 22a collects the manufacturing data indicating the manufacturing result and/or quality of the semiconductor wafer, each chip of which is tested in the test device 21, and has the recording unit 22b record the data. The manufacturing data is expressed in a form in which one lot includes a plurality of semiconductor wafers. Therefore, as shown in FIG. 5, the manufacturing data recorded in the recording unit 22b comprises a model name indicating the type of chips formed on a semiconductor wafer, a lot number indicating the lot of the semiconductor wafer, and data indicating the quality of the semiconductor wafer. In addition, the model name, lot number, etc. are expressed in accordance with the form that is used in the consignee company Y. In the above example, “Y1,” “Y2,” etc. are used as the model name and “Y-12,” “Y-21,” etc. are used as the lot number.

The data transfer and processing unit 22c shown in FIG. 4 reads out the manufacturing data recorded in the recording unit 22b and transfers the read manufacturing data to the manufacturing information service system 40 (FIG. 1) of the manufacturing information service company W via the network N2, the FW 23, and the Internet 60.

Referring to FIG. 1 again, the assembling step control system 30 of the consignee company Z comprises: an assembling and manufacturing device 31 that cuts a semiconductor wafer into chips, gives a post-processing step (assembling step) to conforming chips, and further performs a final test for finally testing whether or not the assembled semiconductor device is a conforming article; an assembling step control server 32 that stores manufacturing data indicating the manufacturing result such as lot progress, inventory information, etc. and/or the quality of the manufactured semiconductor device including the final test result; and an FW 33 that prevents unauthorized access. Here, the assembling step control server 32 is connected to the assembling and manufacturing device 31, and further to the Internet 60 via a network N3 such as LAN, etc. and the FW 33.

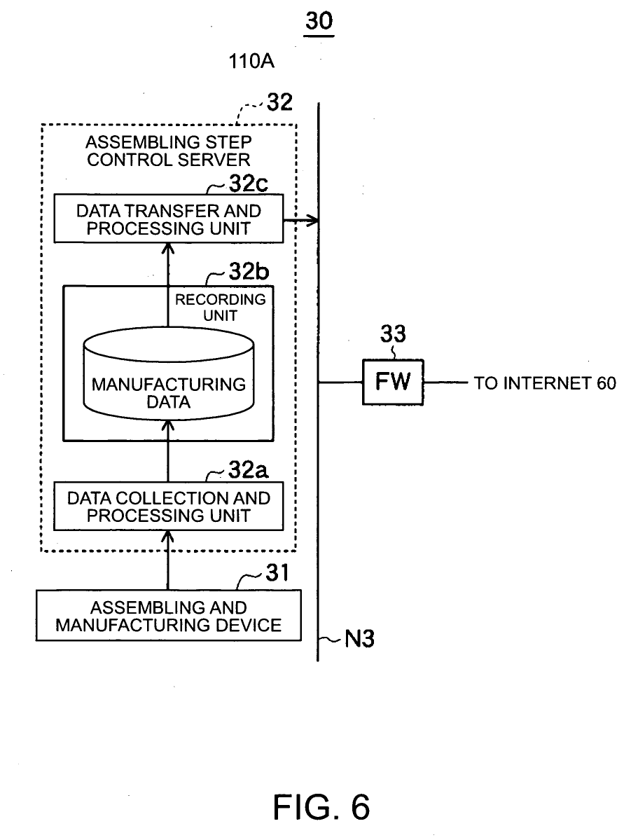

Next, the assembling step control system will be described in detail with reference to FIG. 6. In the assembling step control system 30, the assembling and manufacturing device 31 checks the electric properties of each semiconductor device by: giving, to the cut conforming chips, assembling steps such as a die bonding step, a wire bonding step, a sealing step, etc.; applying a specified voltage to each assembled semiconductor device; and measuring the voltage or current, etc. outputted from each semiconductor device. Further, in the assembling and manufacturing device 31, a final test for judging whether or not each semiconductor device is a conforming article is performed. The semiconductor device judged as a conforming article in the assembling step is shipped to the customer company A.

The assembling step control server 32 comprises a data collection and processing unit 32a that collects manufacturing data indicating the manufacturing result and/or the final test result of a semiconductor device manufactured in the assembling device 31, a recording unit 32b that records the manufacturing data, and a data transfer and processing unit 32c that transfers the manufacturing data recorded in the recording unit 32b to the manufacturing information service system 40 (FIG. 1) of the manufacturing information service company W.

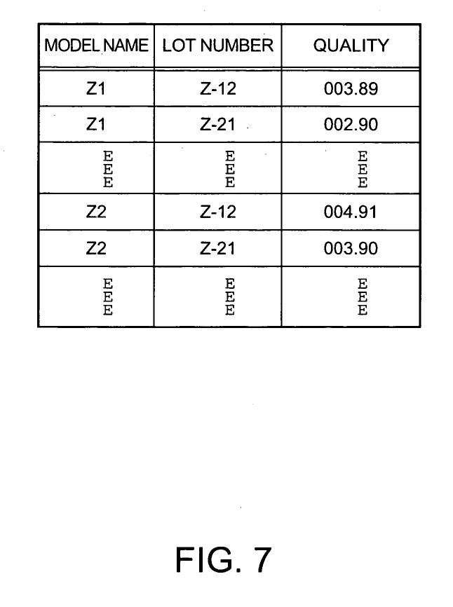

The data collection and processing unit 32a collects manufacturing data indicating the manufacturing result and/or quality of the semiconductor wafer with which a semiconductor device is manufactured in the assembling device 31 and has the recording unit 32b record the data. The manufacturing data is expressed, also in the consignee company Z, in a form in which one lot includes a plurality of semiconductor wafers. Therefore, as shown in FIG. 7, the manufacturing data recorded in the recording unit 32b comprises a model name indicating the type of a semiconductor device, a lot number indicating the lot of the semiconductor device, and data indicating the quality of the semiconductor device. In addition, the model name, lot number, etc. are expressed in accordance with the form that is used in the consignee company Z. In the above example, “Z1,” “Z2,” etc. are used as the model name and “Z-12,” “Z-21,” etc. are used as the lot number.

The data transfer and processing unit 32c shown in FIG. 6 reads out the manufacturing data recorded in the recording unit 32b and transfers the read manufacturing data to the manufacturing information service system 40 (FIG. 1) of the manufacturing information service company W via the network N3, the FW 33, and the Internet 60.

Referring to FIG. 1 again, the manufacturing information service system 40 of the manufacturing information service company W comprises: a manufacturing information service server 41 that stores manufacturing data sent from the processing step control server 12, the probe test step control server 22, and the assembling step control server 32 and further, by converting such data into the data in accordance with the form used in the customer company A, provides such data to a customer company; and an FW 42 that prevents unauthorized access. Here, the manufacturing information service server 41 is connected to the Internet 60 via a network N4 such as LAN, etc. and the FW 42.

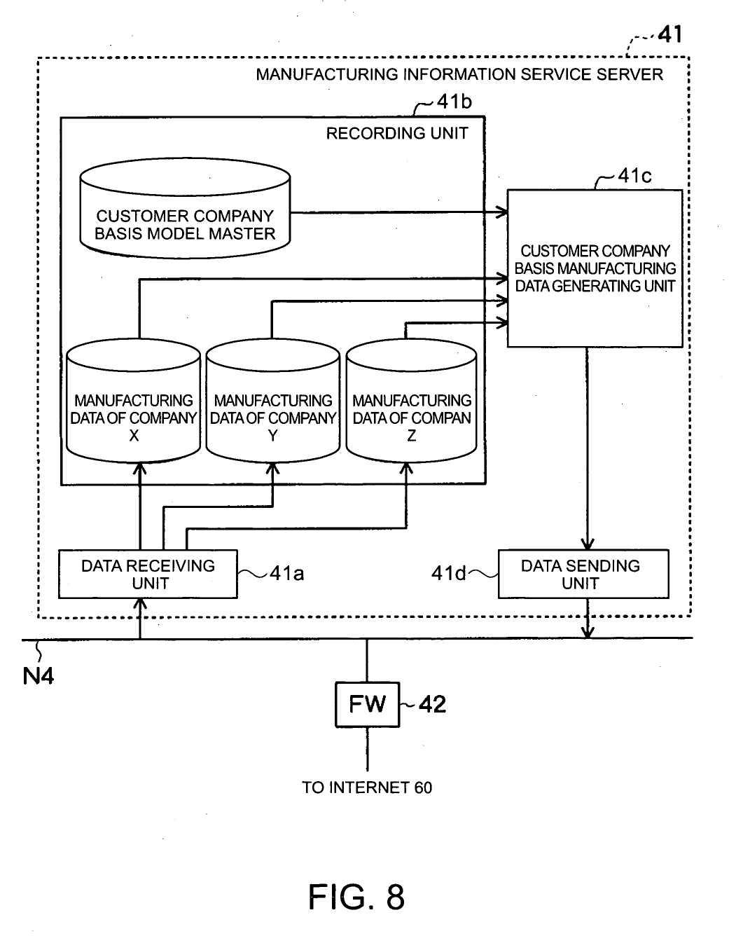

Next, the manufacturing information service system will be described in detail with reference to FIG. 8. In the manufacturing information service system 40, the manufacturing information service server 41 comprises a data receiving unit 41a that receives the manufacturing data, a recording unit 41b that records the manufacturing data, etc., a customer company basis manufacturing data generating unit 41c that generates the manufacturing data on a customer company basis with reference to the manufacturing data recorded in the recording unit 41b, and a data sending unit 41d that sends the manufacturing data intended for a customer company to the production and sales system 50 (FIG. 1) of the customer company A.

The data receiving unit 41a receives each manufacturing data sent from the processing step control server 12 of the consignee company X, the probe test step control server 22 of the consignee company Y, and the assembling step control server 32 of the consignee company Z, shown in FIG. 1, via the Internet 60, an FW 42, and a network N4, and further has the recording unit 41b record the received manufacturing data correspondingly to each company name.

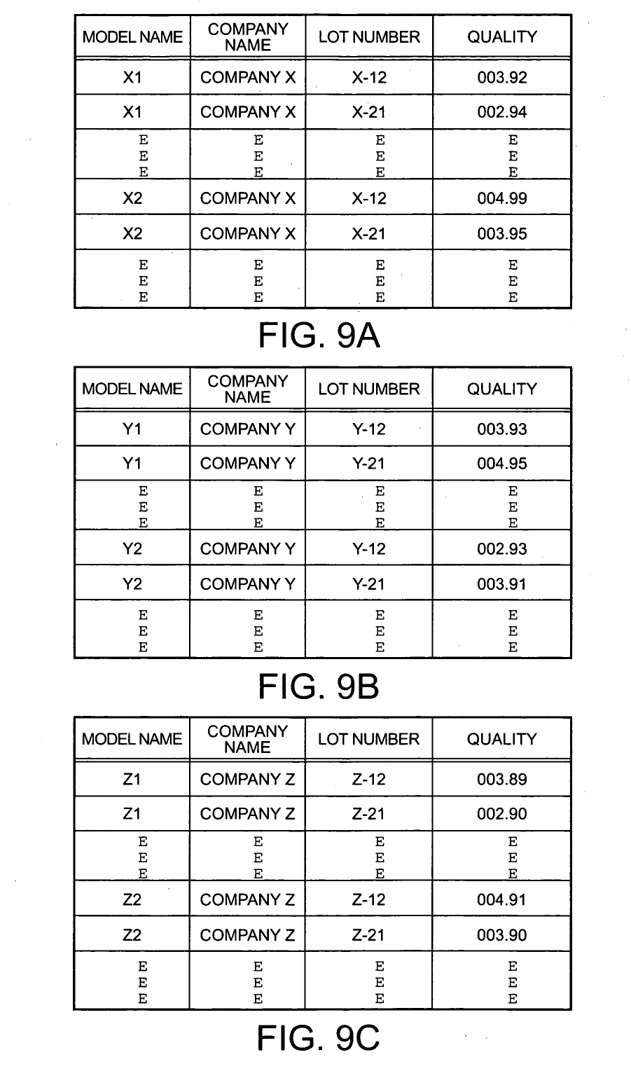

As shown in FIG. 9A, for example, the manufacturing data sent from the processing step control server 12 equipped in the consignee company X is recorded as the manufacturing data of a company X correspondingly to a company name “Company X.” Likewise, as shown in FIG. 9B, the manufacturing data sent from the probe test step control server 22 equipped in the consignee company Y is recorded as the manufacturing data of a company Y correspondingly to a company name “Company Y,” and, as shown in FIG. 9C, the manufacturing data sent from the assembling step control server 32 equipped in the consignee company Z is recorded as the manufacturing data of a company Z correspondingly to a company name “Company Z.”

The recording unit 41b records not only the manufacturing data of the company X, the manufacturing data of the company Y, and the manufacturing data of the company Z but also a customer company basis model master including a conversion table for converting the model name, lot number, etc. expressed in a form that is used in each consignee company into the ones in a form that is used in the customer company.

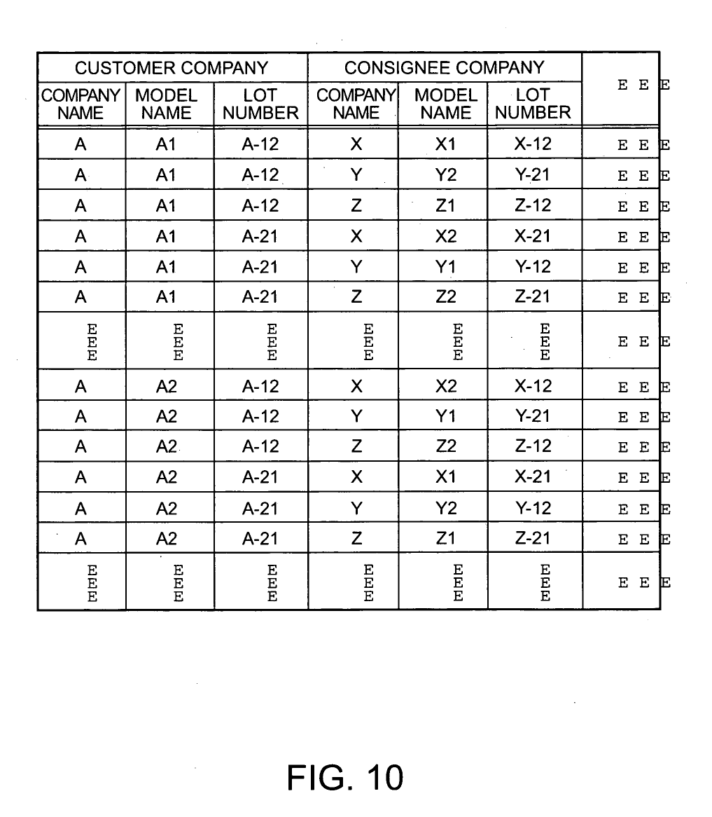

FIG. 10 is a drawing for describing the customer company basis model master. As shown in FIG. 10, the correspondence between the model name and lot number in the customer company and the model name and lot number in the consignee company is given by the customer company basis model master. Specifically, a model name “A1” and a lot number “A-12” in the customer company A having a company name “A” are made correspondent to: a model name “X1” and a lot number “X” in the consignee company X having a company name “X”; a model name “Y2” and a lot number, “Y-21” in the consignee company Y having a company name “Y”; and a model name “Z1” and a lot number “Z” in the consignee company Z having a company name

Further, it is possible to store, into the customer company basis model master, the size; price; model consignment plan; manufacture start date and planned manufacture end date for each lot; etc., giving correspondence to the model names and lot numbers in the customer company.

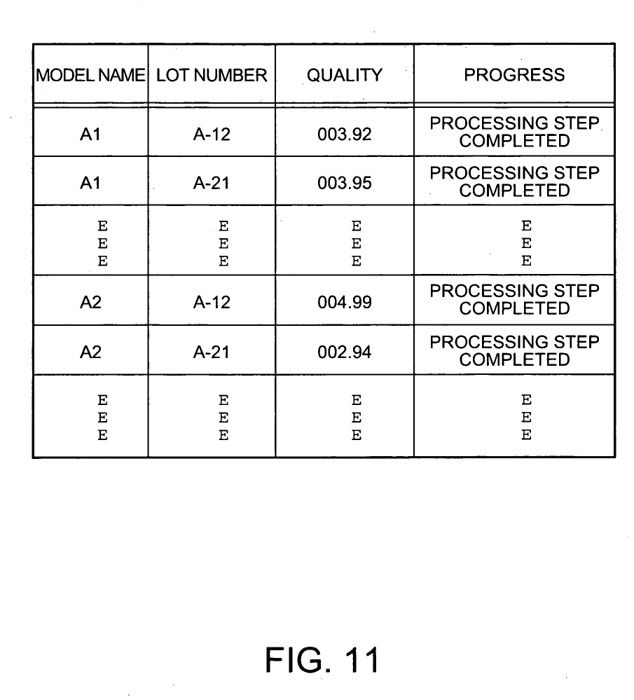

The customer company basis manufacturing data generating unit 41c shown in FIG. 8 converts the manufacturing data of each consignee company that is stored in the recording unit 41b into the manufacturing data intended for the customer company, based on the contents registered in the customer company basis model master. For example, when the manufacturing data of the company X shown in FIG. 3B is received by the data receiving unit 41a and recorded in the recording unit 41b, the customer company basis manufacturing data generating unit 41c generates the manufacturing data shown in FIG. 11, based on the correspondence between the model name and lot number in the customer company A and the model name and lot number in the consignee company X that are registered in the customer company basis model master.

As shown in FIG. 11, the customer company basis manufacturing data generating unit 41c changes the order of data into a specified order by converting the model name and lot number in the consignee company X into the model name and lot number in the customer company A and, at the same time, generates manufacturing data for each customer company by adding progress information indicating “processing step completed,” etc. Thus, the use of a uniform format becomes possible on a customer company basis without depending on the format used in the consignee company. Therefore, the management of semiconductor device manufacturing steps in the customer company becomes easier.

The manufacturing data generated as above is sent by the data sending unit 41d shown in FIG. 8 to the production and sales control system 50 (FIG. 1) of the customer company A via the network N4, the FW 42, and the Internet 60. In addition, the manufacturing data can also be sent using a web page and an e-mail. Alternatively, a manufacturing data file can be generated and transferred via an exclusive circuit.

Referring to FIG. 1 again, the production and sales control system 50 comprises: the production and sales control server 51 that receives and records the manufacturing data sent from the manufacturing information service server 41 of the manufacturing information service company W; a client terminal 52 that displays or prints, based on the manufacturing data, a screen for checking the manufacturing result and/or the quality; and an FW 53 that prevents unauthorized access. Here, the production and sales control server 51 and the client terminal 52 are connected to a network N5, and further to the Internet 60 via the FW 53.

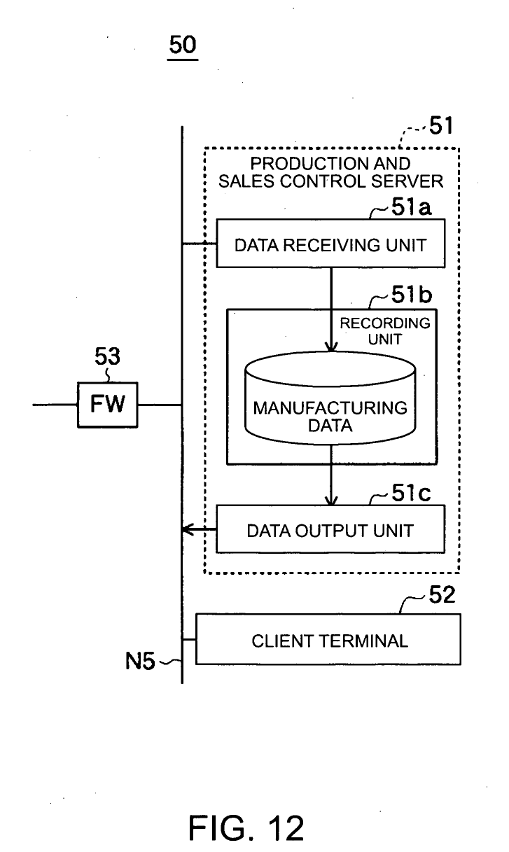

Next, the production and sales control system will be described in detail with reference to FIG. 12. The production and sales control server 51 comprises a data receiving unit 51a that receives the manufacturing data, a recording unit 51b that records the manufacturing data, etc., and a data output unit 51c that outputs, to the client terminal 52, the manufacturing data recorded in the recording unit 51b.

The data receiving unit 51a receives the manufacturing data intended for the customer company A sent from the manufacturing information service server 41 of the manufacturing information service company W shown in FIG. 1, via the Internet 60, the FW 53, and the network N5, and further has the recording unit 51b record the received manufacturing data.

The manufacturing data recorded in the recording unit 51b is read out by the data output unit 51c and outputted to the client terminal 52 via the network N5. In the client terminal 52, the progress information and manufacturing quality in the semiconductor device manufacturing steps are displayed on a screen or printed from a printer, based on the inputted manufacturing data. Thus, in the customer company A, there will be no more need of having negotiations for the provision of manufacturing data with each consignee company in order to collect the production control information and quality control information of a semiconductor device, and therefore laborsaving can be achieved. Further, since the manufacturing data of the consignee companies is fed back to the customer company in an uniform format independent of the consignee companies, the customer company can easily take prompter actions for supplying products.

### FIELD OF INDUSTRIAL APPLICATION

The present invention can be applied to a semiconductor device manufacturing information service system for providing production control information and quality control information to a customer company when another company that supplies semiconductor devices produces a semiconductor device by consigning at least one of manufacturing steps in the manufacture of a semiconductor device to at least one consignee company.

1. A semiconductor device manufacturing information service system for providing information on a manufacture of a semiconductor device to a first company, which is a customer, when a semiconductor device is produced by consigning, from a second company to at least one third company, at least one of manufacturing steps required in the manufacture of a semiconductor device ordered from the first company to the second company, comprising:
at least one process control server, which is equipped in the at least one third company, that collects and stores manufacturing data indicating a manufacturing result and/or quality in a manufacturing step accepted by the at least one third company;
a manufacturing information service server, which is equipped in the second company, that generates manufacturing data, which is to be used in the first company, on a customer company basis by receiving, via a network, the manufacturing data sent from the at least one process control server and changing a form of the manufacturing data using a pre-recorded conversion table; and
a production and sales control server, which is equipped in the first company, that receives, via a network, the manufacturing data on a customer company basis sent from the manufacturing information service server and then displays or prints the data.

2. The semiconductor device manufacturing information service system according to claim 1, wherein the at least one third company accepts at least one of semiconductor device manufacturing steps including a processing step, a probe test step, an assembling step, and a final test step.

3. The semiconductor device manufacturing information service system according to claim 1, wherein the at least one process control server collects and stores manufacturing data containing data indicating a model name and a lot number of a semiconductor device manufactured in the manufacturing step accepted by the at least one third company.

4. The semiconductor device manufacturing information service system according to claim 1, wherein the at least one process control server collects and stores manufacturing data containing data indicating a test result of a semiconductor device manufactured in the manufacturing step accepted by at least one third company.

5. The semiconductor device manufacturing information service system according to claim 3, wherein the manufacturing information service server converts the data indicating a model name and a lot number of a semiconductor device that are used in the at least one third company into data indicating a model name and a lot number of a semiconductor device that are used in the first company.

6. A manufacturing information service server that is equipped in a second company for providing information on a manufacture of a semiconductor device to a first company, which is a customer, when a semiconductor device is produced by consigning, from the second company to at least one third company, at least one of manufacturing steps required in the manufacture of a semiconductor device ordered from the first company to the second company, comprising:
a receiving means for receiving, from the at least one process control server equipped in the at least one third company and via a network, manufacturing data indicating a manufacturing result and/or quality in a manufacturing step accepted by the at least one third company;
a recording means for recording a conversion table used for converting a manufacturing data form between the at least one third company and the first company;
a data generating means for generating manufacturing data on a customer company basis, which is to be used in the first company, by changing, using the conversion table recorded in the recording means, a form of the manufacturing data received from the at least one process control server; and
a sending means for sending, via a network, the manufacturing data on a customer company basis generated by the data generating means to the production and sales control server equipped in the first company.

7. The manufacturing information service server according to claim 6, wherein the data generating means converts data indicating a model name and a lot number of a semiconductor device that are used in the at least one third company into data indicating a model name and a lot number of a semiconductor device that are used in the first company.
